(19) United States
(12) Patent Application Publication
(10) Pub. No.: US 2025/0203890 A1
(43) Pub. Date: Jun. 19, 2025

(54) FERROELECTRIC MEMORY DEVICES

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/539,202

(22) Filed: Dec. 13, 2023

(51) Int. Cl. H10B 53/30

(52) U.S. Cl. CPC H10D 1/684; H10B 53/30

(57) ABSTRACT

In accordance with some embodiments of the present disclosure, a memory device is provided. The memory device may include a first electrode, a ferroelectric layer fabricated on the first electrode, and a second electrode fabricated on the ferroelectric layer. The ferroelectric layer includes a plurality of ferroelectric films and a plurality of interface layers stacked alternately. Each of the ferroelectric films comprises at least one ferroelectric material, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. Each of the interface layers comprises at least one dielectric material that is more chemically stable than the ferroelectric material, such as aluminum oxide.

### TECHNICAL FIELD

The implementations of the disclosure relate generally to memory and computing devices and, more specifically, to ferroelectric memory devices.

### BACKGROUND

Ferroelectric materials may refer to materials that exhibit a spontaneous electric polarization that can be reversed in direction by the application of a suitable electric field, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. The ferroelectric materials may remain polarized even when the electric field is removed. As such, the ferroelectric materials may store data when power is disconnected from it. This makes the ferroelectric materials promising candidates for implementing non-volatile memory that remains stored data even when its external power supply is disconnected.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a memory device is provided. The memory device may include a first electrode; a ferroelectric layer fabricated on the first electrode; and a second electrode fabricated on the ferroelectric layer. The ferroelectric layer includes a plurality of ferroelectric films and a plurality of interface layers stacked alternately. Each of the plurality of ferroelectric films includes a ferroelectric material. Each of the plurality of interface layers includes at least one dielectric material that is more chemically stable than the ferroelectric material.

In some embodiments, the ferroelectric material includes a metal oxide, and wherein the metal oxide includes at least one of hafnium oxide (HfO₂), zirconium oxide (ZrO₂), zirconium-doped hafnium oxide (Hf₁₋ₓZrₓO₂ with x ranging from 0 to 1) scandium-doped aluminum nitride (Al₁₋ₓScₓN with x>0.3), titanates (BaTiO₃), niobates (LiNbO₃), or tantalates (NaTaO₃).

In some embodiments, the ferroelectric material is interstitially doped with at least one interstitial dopant, and wherein the at least one interstitial dopant includes at least one of H, N, C, B, or F.

In some embodiments, the plurality of ferroelectric films includes a first ferroelectric film and a second ferroelectric film, and wherein a first interface layer of the plurality of interface layers is fabricated between the first ferroelectric film and the second ferroelectric film.

In some embodiments, the first interface layer includes a discontinuous film of the dielectric material, wherein at least a portion of the second ferroelectric film is directly fabricated on the first ferroelectric film through pin-holes or pores in the interface layer.

In some embodiments, the second electrode is fabricated on a top ferroelectric film of the plurality of ferroelectric films.

In some embodiments, the dielectric material includes aluminum oxide.

In some embodiments, the first electrode includes at least one of tungsten, ruthenium, molybdenum, titanium nitride, tantalum nitride, or tungsten nitride.

In some embodiments, the second electrode includes at least one of tungsten, ruthenium, molybdenum, titanium nitride, tantalum nitride, or tungsten nitride.

According to one or more aspects of the present disclosure, methods for fabricating a memory device are provided. The methods include fabricating, on a first electrode, a ferroelectric layer; and fabricating, on the ferroelectric layer, a second electrode. The ferroelectric layer includes a plurality of ferroelectric films and a plurality of interface layers alternately stacked. Each of the plurality of ferroelectric films includes a ferroelectric material. Each of the plurality of interface layers includes at least one dielectric material that is more chemically stable than the ferroelectric material.

In some embodiments, the ferroelectric material includes a metal oxide, and wherein the metal oxide includes at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

In some embodiments, the ferroelectric material is interstitially doped with at least one interstitial dopant, and wherein the interstitial dopant includes at least one of H, N, C, B, or F.

In some embodiments, fabricating the ferroelectric layer includes fabricating a first ferroelectric film; fabricating, on the first ferroelectric film, a first interface layer of the plurality of interface layers; and fabricating a second ferroelectric film on the first interface layer.

In some embodiments, fabricating the first interface layer includes fabricating a discontinuous film of the dielectric material, wherein at least a portion of the second ferroelectric film is directly fabricated on the first ferroelectric film through the discontinuous film of dielectric material.

In some embodiments, the first ferroelectric film is fabricated by depositing the ferroelectric material using Atomic Layer Deposition (ALD). The first interface layer is fabricated by depositing the dielectric material using ALD.

In some embodiments, the second electrode is fabricated on a top ferroelectric film of the plurality of ferroelectric films.

In some embodiments, the dielectric material includes aluminum oxide.

In some embodiments, the first electrode includes at least one of tungsten, ruthenium, molybdenum, titanium nitride, tantalum nitride, or tungsten nitride.

In some embodiments, the second electrode includes at least one of tungsten, ruthenium, molybdenum, titanium nitride, tantalum nitride, or tungsten nitride.

In some embodiments, the methods further include performing heat treatment on the memory device.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a cross-sectional view of an example of a memory device in accordance with some embodiments of the present disclosure.

FIG. 2 is a cross-sectional view of an example of a ferroelectric layer in accordance with some embodiments of the present disclosure.

FIGS. 3A, 3B, 3C, 3D, 3E, 3F, 3G, and 3H illustrate cross-sectional views of structures for fabricating a memory device 300 in accordance with some embodiments of the present disclosure.

FIG. 4 is a flow chart illustrating an example process for fabricating a memory device in accordance with some embodiments of the present disclosure.

FIG. 5 is a flow chart illustrating an example process for fabricating a ferroelectric layer of a memory device in accordance with some embodiments of the present disclosure.

### DETAILED DESCRIPTION

Aspects of the present disclosure provide ferroelectric memory devices and methods for making the same. The ferroelectric memory devices may be part of ferroelectric random-access memories (Fe-RAM), such as a capacitor (e.g., ferroelectric capacitor (FeCAP)), a transistor (e.g., ferroelectric field-effect transistor (FeFET)), a ferroelectric tunneling junction (FTJ), a ferroelectric random-access memory (FeRAM), etc.

A ferroelectric material may be polarized in response to the application of an external electric field and may remain polarized even when the external electric field is removed. The reversible spontaneous polarization arises from non-centrosymmetric arrangements of ions in the ferroelectric material that produces a permanent electric dipole moment. Adjacent dipoles tend to orient themselves in the same direction to form a region referred to as a ferroelectric domain.

A material may have multiple polymorphs of varying ferroelectric properties. For example, HfO₂ may exhibit a monoclinic phase (m-phase) between room temperature and 1670° C. As the temperature increases, HfO₂ may undergo a phase transition from monoclinic (m-phase) to tetragonal (t-phase) and then to cubic (c-phase). HfO₂ does not exhibit ferroelectricity in the m-phase, the t-phase, or the c-phase. HfO₂ may exhibit ferroelectricity in a polar orthorhombic phase (o-phase). Although the m-HfO₂ phase is the most stable phase around ambient temperature thermodynamically, the o-HfO₂ phase shows distinctive properties due to its intrinsic non-centrosymmetric polar and ferroelectric behavior. Ferroelectricity in materials relates to the permanent electrical polarization of a crystalline dielectric under an electric field. Ferroelectric materials exhibit bi-state polarization behaviors, enabling them to store binary information of “0” and “1” in a non-volatile manner, making them suitable for memory devices

Under extremely high pressures of 1 gigapascal (approximately 10,000 atmospheres), orthorhombic phases of HfO₂ materials exist, designated as Orthorhombic-I (oI-phase) and Orthorhombic-II (oII-phase). The ferroelectric phase required for certain applications is Orthorhombic-III (oIII-phase), which is characterized by the Miller index Pca2₁. This oIII-phase does not appear in the equilibrium phase diagram and may need to be synthesized through a process that is either favored or controlled by the kinetics of the reaction. Due to the kinetic favorability of the oIII-phase and the thermodynamically preferred m-phase, both the ferroelectric oIII-phase and the non-ferroelectric m-phase may co-exist in ferroelectric devices. This may occur when insufficient oIII formation in the device and can result in inadequate ferroelectric signal strength. To amplify signal intensity, one approach is to increase the thickness of the device film, thereby enhancing the amount of oIII-phase present. However, merely enlarging the lateral size of the device will not address this issue. A thicker film may lead to larger polycrystalline grain size and more variability at the grain boundaries, potentially increasing the device's leakage current. Additionally, smaller grain size corresponds to reduced ferroelectric domain size, since a single grain may contain multiple ferroelectric domain sizes. Moreover, a higher number of domains could provide multiple domain wall orientations, such as 0 degrees (parallel), 180 degrees (anti-parallel), and other orientations, which is beneficial for multilevel Fe-RAM applications.

The present disclosure provides ferroelectric memory devices and methods for fabricating the same. The ferroelectric memory devices include sufficient ferroelectric materials in the desirable oIII-phase, making them suitable for implementing Fe-RAM applications. In accordance with some embodiments of the present disclosure, a memory device may include a ferroelectric layer fabricated between two electrodes. The ferroelectric layer may include a multilayer structure of multiple ferroelectric films and interface layers alternately stacked on each other. For example, the fabrication of the ferroelectric layer may involve a fabricating process, in which a thin film of a ferroelectric material (e.g., HfO or HZO) is deposited on a first electrode and a thin layer of aluminum oxide (e.g., Al₂O₃) is deposited on top of the ferroelectric film. This fabrication process may be repeated a suitable number of times to create a layered structure of a desirable thickness. In some embodiments, a top ferroelectric layer (e.g., a layer of HfO, a layer of HZO, etc.) may be fabricated on the multilayer structure. A second electrode may be fabricated on the top ferroelectric layer. In some embodiments, the second electrode may be fabricated directly on the multilayer structure. A heat treatment process, including controlled heating and cooling steps, may be performed to transform the amorphous ferroelectric film into the desired crystalline ferroelectric phases (e.g., oIII-phase). This may be achieved using rapid thermal annealing (RTA), for instance, at a temperature of 450° C. for 30 seconds followed by rapid cooling. The ferroelectric layer may further include some non-ferroelectric phase (e.g., t-phase) material, which may later transform into the ferroelectric phase (for example, through a wakeup effect). The memory device described herein may be a non-volatile memory device that retains stored data even when it is not powered.

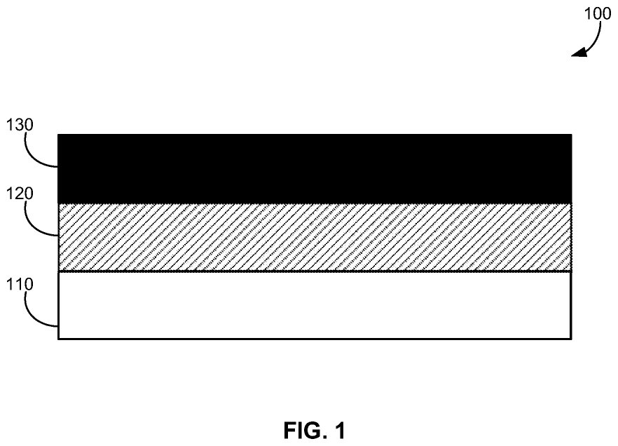

FIG. 1 is a cross-sectional view of an example 100 of a memory device in accordance with some embodiments of the present disclosure. As shown, memory device 100 may include a first electrode 110, a ferroelectric layer 120, and a second electrode 130. The memory device 100 may be a non-volatile memory device that can retain stored data even when it is not powered.

The first electrode 110 and the second electrode 130 may or may not include the same material. First electrode 110 may be fabricated on a substrate (not shown in FIG. 1) using physical vapor deposition (PVD), atomic layer deposition (ALD), and/or any other suitable deposition technique. First electrode 110 may include any suitable electrically conductive material. As an example, first electrode 110 may include metals such as tungsten (W), ruthenium (Ru), molybdenum (Mo), etc. As another example, first electrode 110 may include nitrides, such as titanium nitride (TiN), tantalum nitride (TaN), tungsten nitride (WN), etc.

Ferroelectric layer 120 may include multiple ferroelectric films and multiple interface layers alternately stacked on each other. Each of the ferroelectric films may include a ferroelectric material. The ferroelectric material may include a metal oxide, such as hafnium oxide (HfO₂), zirconium oxide (ZrO₂), zirconium-doped hafnium oxide (Hf₁₋ₓZrₓO₂) with x ranging from 0 to 1, scandium-doped aluminum nitride (Al₁₋ₓScₓN) with x>0.3, titanates (BaTiO₃), niobates (LiNbO₃), tantalates (NaTaO₃), etc. In some embodiments, the metal oxide may be doped with one or more substitutional and/or interstitial dopants that may occupy the vacant space between the atoms of the ferroelectric material. The interstitial dopant may include an element having an atomic radius that is not greater than an atomic radius of a metal element of the metal oxide. The metal oxide may include at least one of hafnium or zirconium. The interstitial dopant may include a nonmetal element, such as H, N, C, B, F, etc. The interstitial dopants may be introduced in the ferroelectric film utilizing an ion implantation method, a co-sputtering method, an alternating sputtering method, a thermal diffusion method, a chemical absorption method, and/or any other suitable technique. In some embodiments, the dopant concentration of the interstitial dopants(s) may be about or less than 10%.

Second electrode 130 may include any suitable electrically conductive material. For example, second electrode 130 may include metals, such as W, Ru, Mo, etc., and/or nitrides (e.g., TiN, TaN, WN, etc.). Second electrode 130 and first electrode 110 may or may not include the same materials.

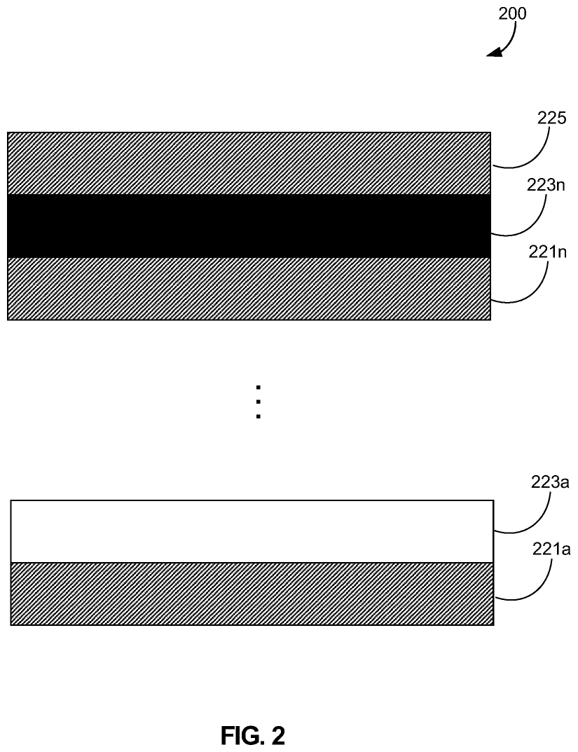

FIG. 2 is a cross-sectional view of an example 200 of a ferroelectric layer in accordance with some embodiments of the present disclosure.

As shown, ferroelectric layer 200 may include a plurality of ferroelectric film and a plurality of interface layers stacked alternately. For example, a first interface layer 223a may be fabricated on a first ferroelectric film 221a. The nth interface layer 223n (also referred to as the “top interface layer”) may be fabricated on the nth ferroelectric film 221n. A ferroelectric film 225 (also referred to as the “top ferroelectric film”) may be fabricated on the nth interface layer 223n. In some embodiments, the top ferroelectric film 225 may be omitted from ferroelectric layer 200. Each ferroelectric film 221a, . . . , 221n may include a film of one or more ferroelectric materials. The ferroelectric materials may include a metal oxide, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), or tantalates (NaTaO₃).

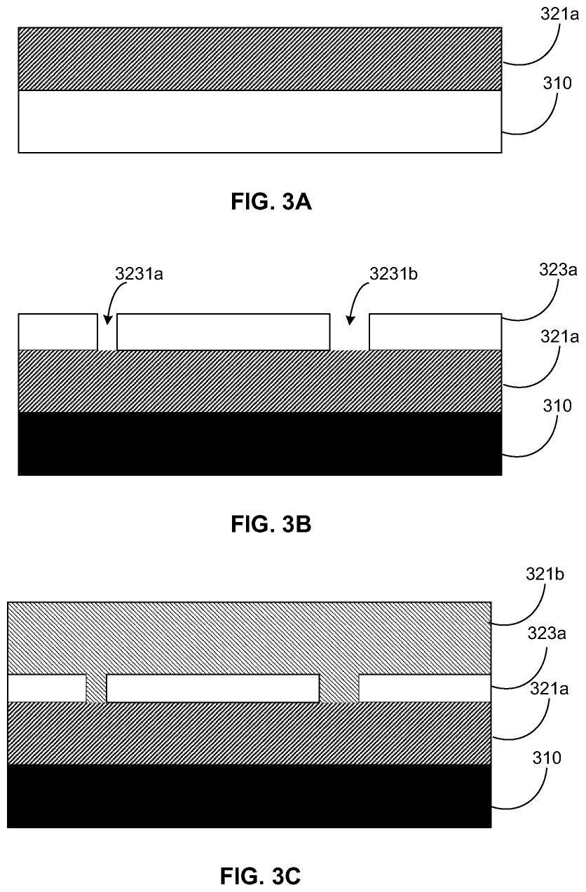

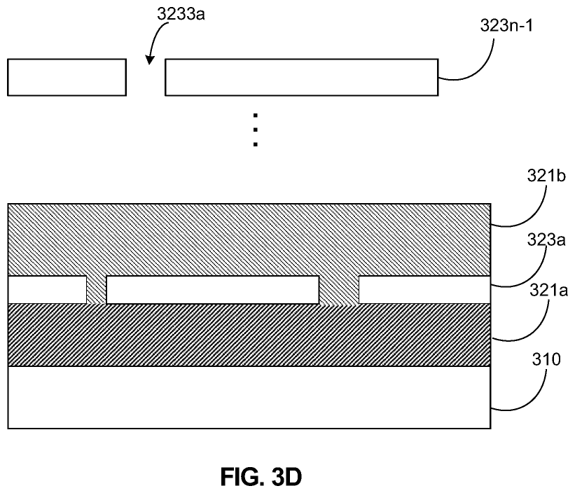

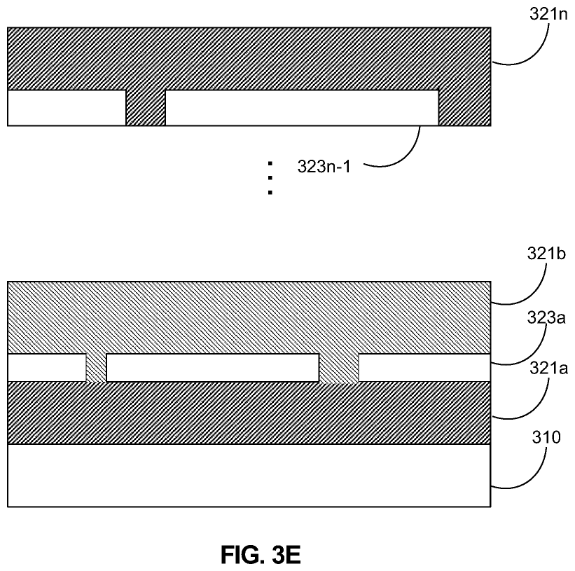

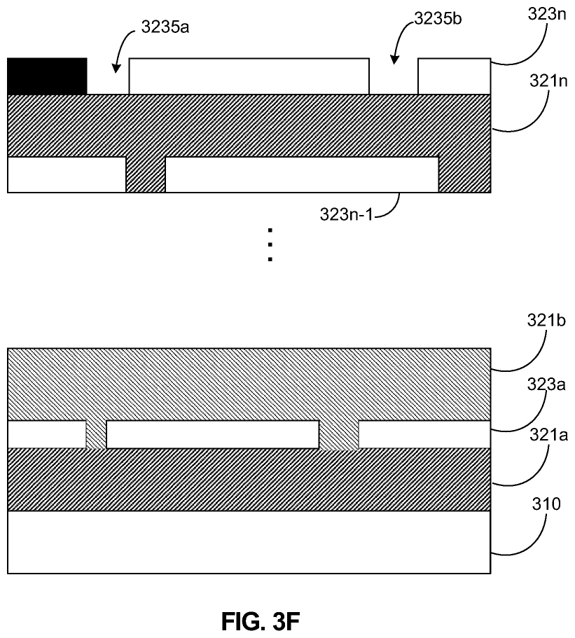

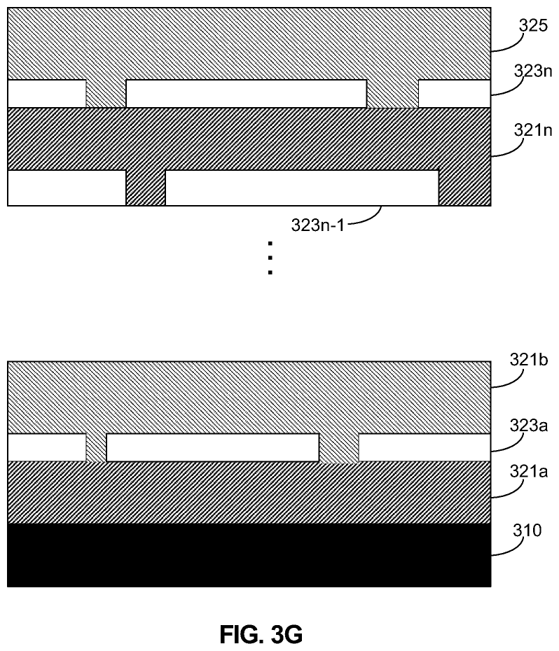

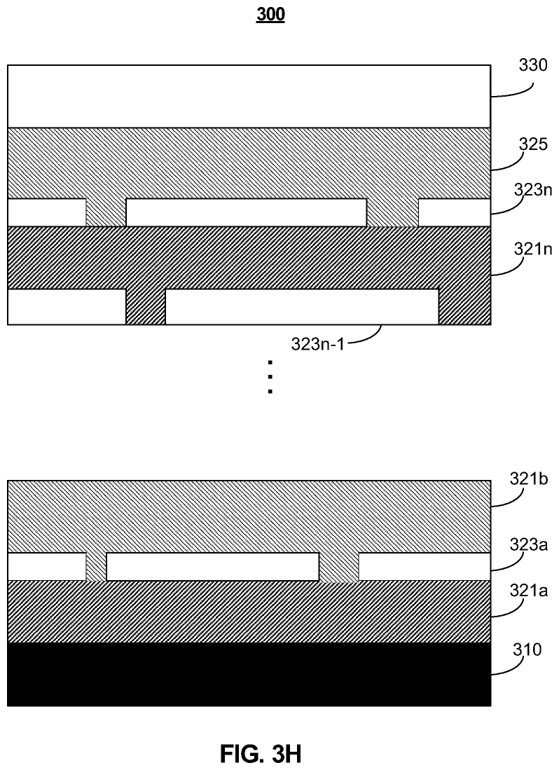

Each of interface layers 223a, . . . , 223n may include a dielectric material that is more chemically stable than the ferroelectric materials in the ferroelectric films. As a result, the dielectric material may not react with the ferroelectric materials in the ferroelectric films. Examples of the dielectric materials may include Al₂O₃, SiO₂, Si₃N₄, MgO, Y₂O₃, Gb₂O₃, Sm₂O₃, CeO₂, Er₂O₃, La₂O₃, etc. In some embodiments, as will be discussed in greater detail in connection with FIGS. 3A-3H, one or more interface layers 223a, . . . , 223n may be and/or include a discontinuous layer of the dielectric material.

The configuration of the ferroelectric films and the interface layers may be determined based on the desirable size of the memory device to be fabricated. For example, the size/thickness of ferroelectric layer 200 may be defined as (n1+n2)*n3+n4, where (n1+n2) represents a sub-cycle of a pair of a ferroelectric film and an interface layer; n1 is the film thickness in nanometers of the ferroelectric layer; n2 is the film thickness in nanometers of the non-ferroelectric interface layer; n3 is the number of sub-cycles; and n4 is the top film thickness in nanometers of the ferroelectric layer. n4 can be the same or different from n1. As a more particular example, ferroelectric layer 200 may include a film with 3 nm of HfO₂ plus 0.3 nm of Al₂O₃, repeated for 3 cycles, topped with an additional 3 nm of HfO₂. As another more particular example, ferroelectric layer 200 may include film with 2 nm of HfO₂ plus 0.2 nm of Al₂O₃, repeated for 4 cycles, topped with an additional 2 nm of HfO₂. As a further example, ferroelectric layer 200 may include a film with 1.5 nm of HfO₂ plus 0.2 nm of Al₂O₃, repeated for 5 cycles, topped with an additional 2 nm of HfO₂. As still a further example, ferroelectric layer 200 may include a film with 1 nm of HfO₂ plus 0.2 nm of Al₂O₃, repeated for 7 cycles, topped with an additional 1.5 nm of HfO₂.

The combination of the interface layers and ferroelectric films may increase the amount of ferroelectric oIII-phase by promoting the nucleation of the oIII-phase, thereby enhancing the ferroelectric signal strength, while controlling the grain sizes and grain boundary sizes of the ferroelectric phase in the ferroelectric films. This is achieved through the presence of interface layers which may reduce the nucleation barrier of the oIII-phase, resulting in more ferroelectric grains with smaller ferroelectric grain sizes.

FIGS. 3A, 3B, 3C, 3D, 3E, 3F, 3G, and 3H illustrate cross-sectional views of structures for fabricating a memory device 300 in accordance with some embodiments of the present disclosure. Memory device 300 may be a non-volatile ferroelectric memory device.

As shown in FIG. 3A, a ferroelectric film 321a (also referred to as the “first ferroelectric film”) may be fabricated on a first electrode 310. First electrode 310 may be and/or include first electrode 110 of FIG. 1.

As shown in FIG. 3B, an interface layer 323a (also referred to as the “first interface film”) may be fabricated on ferroelectric film 321a. Interface layer 323a may include a discontinuous film of a dielectric layer (or islands of the dielectric layer) with pores and/or pin-holes 3231a, . . . , 3231b that are randomly dispersed in interface layer 323a. While a certain number of pores are illustrated in FIG. 3B, this is merely illustrative. Interface layer 323a may include a random number of pores and/or pin-holes. In some embodiments, a thickness of interface layer 323a may be between about 0.2 nm and about 0.5 nm. In some embodiments, interface layer 323a may be an Al₂O₃ film having a thickness equal to or less than 0.5 nm.

As shown in FIG. 3C, a ferroelectric film 321b (also referred to as the “second ferroelectric film”) may be fabricated on interface layer 323a. One or more portions of ferroelectric film 321b may be directly fabricated on ferroelectric film 321a via pores and/or pin-holes 3231a, . . . , 3231b of interface layer 323a.

One or more additional pairs of a ferroelectric film and an interface layer may be fabricated by repeating the fabrication processes depicted in FIGS. 3B and 3C. As shown in FIG. 3D, an interface layer 323n-1 may be fabricated on ferroelectric film 321b and may or may not directly contact ferroelectric film 321b depending on the number of ferroelectric films and interface layers to be fabricated. In one implementation, interface layer 323n-1 may be directly fabricated on ferroelectric film 321b. In another implementation, interface layer 323n-1 may be fabricated on one or more additional ferroelectric films (not shown) that are fabricated on ferroelectric film 321b. Interface layer 323n-1 may include a discontinuous film of a dielectric layer containing pores and/or pin-holes 3233a that are randomly dispersed within interface layer 323n-1.

As shown in FIG. 3E, a ferroelectric film 321n may be fabricated on interface layer 323n-1. Ferroelectric film 321n may include any suitable ferroelectric material as described herein. The ferroelectric material may be deposited on interface layer 323n-1 and through pin-holes 3233a. As illustrated, one or more portions of ferroelectric film 321n may directly contact the ferroelectric film 321n-1 on which interface layer 323n-1 is directly fabricated.

As shown in FIG. 3F, an interface layer 323n (also referred to as the “top interface layer”) may be fabricated on ferroelectric film 321n. Interface layer 323n may include a discontinuous film of a dielectric layer including pores and/or pin-holes 3235a, . . . , 3235b that are randomly dispersed in interface layer 323n.

In some embodiments, a top ferroelectric film 325 may be fabricated on interface layer 323n as shown in FIG. 3G.

As shown in FIG. 3H, a second electrode 330 may be fabricated on the top ferroelectric film 325 to fabricate memory device 300. Second electrode 330 may be and/or include second electrode 130 of FIG. 1. Memory device 300 may include n+1 ferroelectric films and n interface layers alternately stacked on each other.

Memory device 300 incorporates ultra-thin interface layers (e.g., layers of 0.2 nm, 0.3 nm, 0.4 nm, 0.5 nm, etc.) that each may include a discontinuous film of dielectric materials, such as islands of the dielectric materials and/or a film of the dielectric materials with pinholes. This discontinuity may interrupt the vertical grain growth of the ferroelectric materials in the ferroelectric films, thus controlling the polycrystalline grain sizes and grain boundaries in the ferroelectric films. As a result of its noncontinuous nature, the interface layer may also influence lateral grain growth due to grain growth kinetics and may not function as a full or complete interlayer because of its non-continuous nature. Locally, a small portion of grains may grow across the pinholes in the interface layer. The presence of small grains in the ferroelectric films may decrease variability caused by grain boundaries and reduce leakage current associated with larger grains.

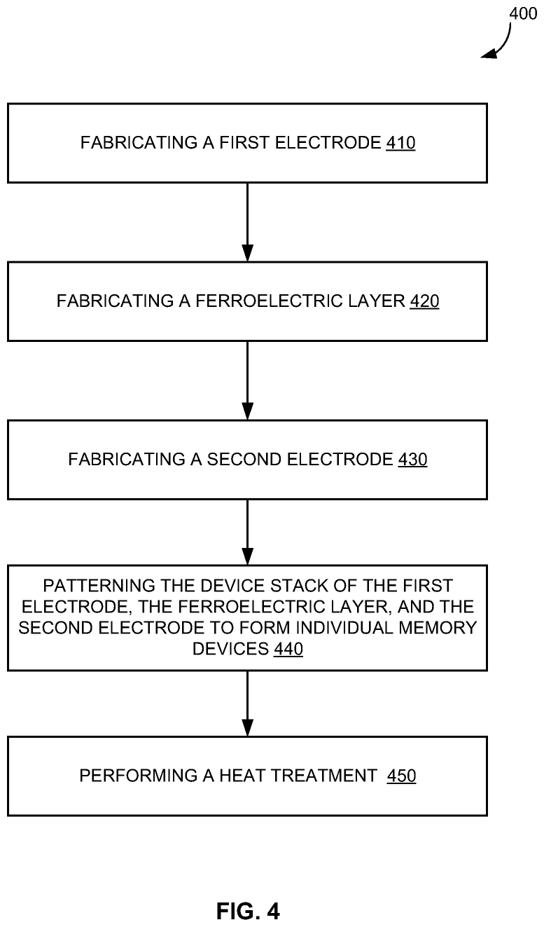

FIG. 4 is a flow chart illustrating an example process 400 for fabricating a memory device in accordance with some embodiments of the present disclosure.

At block 410, a first electrode may be fabricated. For example, a layer of a suitable electrically conductive material may be deposited utilizing atomic layer deposition (ALD), chemical vapor deposition (CVD), metal-organic chemical vapor deposition (MOCVD), physical vapor deposition (PVD), molecular beam epitaxy (MBE) deposition, etc. The electrically conductive material may include, for example, W, Mo, Ru, TiN, TaN, WN, Pt, Pd, Ir, etc.

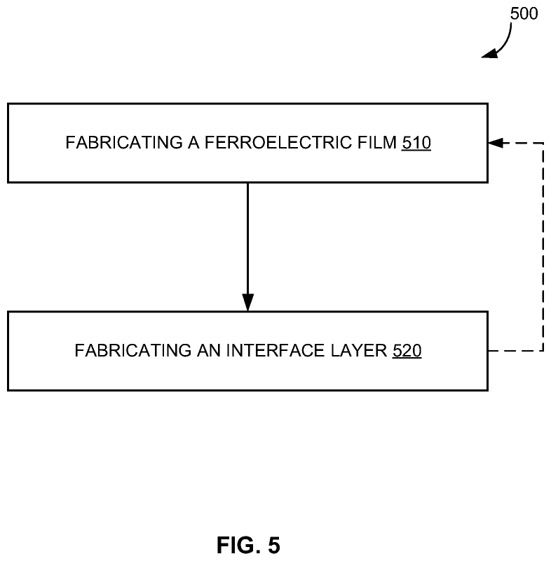

At block 420, a ferroelectric layer may be fabricated on the first electrode. Fabricating the ferroelectric layer may involve alternately fabricating ferroelectric films and interface layers using ALD or other suitable deposition techniques. Each of the ferroelectric films may include at least one ferroelectric material (e.g., HfO₂ (HO), ZrO₂ (ZO), HZO(Hf_{0.5}Zr_{0.5}O₂), HₓZ₁₋ₓO(HfₓZr₁₋ₓO₂) with x ranging from 0 to 1, etc.). Each of the interface layers may include a dielectric material (e.g., Al₂O₃). The ferroelectric films may be ferroelectric films 221a-221n of FIG. 2 and/or ferroelectric films 321a-321n of FIGS. 3A-3H. The interface layers may be 223a-223n of FIG. 2 and/or interface layer 323a-323n of FIGS. 3A-3H. In some embodiments, fabricating the ferroelectric layer may involve performing operations depicted in FIG. 5 iteratively to deposit a ferroelectric layer of a desirable thickness.

At block 430, a second electrode may be fabricated on the ferroelectric layer. For example, a layer of a suitable electrically conductive material may be deposited utilizing suitable deposition techniques, such as ALD, CVD, MOCVD, PVD, MBE, etc.

At block 440, the ferroelectric device stack of the first electrode, the ferroelectric layer, and the second electrode may be patterned to form individual memory devices. The patterning process may involve defining the geometries of the individual memory devices and selectively removing one or more portions of the ferroelectric device stack using suitable etching methods, such as RIE (reactive ion etch), plasma etch, sputter etch, etc.

At block 450, heat treatment, including controlled heating and cooling, may be performed on the memory device(s) to achieve the desired ferroelectric oIII-phase. For example, the heat treatment may involve heating and then cooling the first electrode, the ferroelectric layer, and/or the second electrode at controlled rates. More particularly, for example, the memory device may be heated for crystallization of the t-HfO₂ phase and may then be quickly cooled down to form the ferroelectric o-HfO₂ phase. As a more particular example, amorphous H₂O may be transformed into the t-phase in a heating process and then transformed to the oIII-phase in a subsequent cooling process. This process can be accomplished by performing rapid thermal annealing (RTA) at a temperature of 450° C. (ranging from 400° C. to 500° C.) for a duration of 30 seconds (with a possible range of 15 to 60 seconds). Following the heating process, the memory device may be rapidly cooled.

FIG. 5 is a flow chart illustrating an example process 500 for fabricating a ferroelectric layer of a memory device in accordance with some embodiments of the present disclosure.

At block 510, a ferroelectric film may be fabricated. Fabricating the ferroelectric film may involve, for example, depositing a layer of a ferroelectric material, such as HfO₂, ZrO₂, Hf₁₋ₓZrₓO₂, etc. Fabricating the ferroelectric film may involve fabricating a single-crystalline film of the ferroelectric material, a polycrystalline film of the ferroelectric material, and/or an amorphous film of the ferroelectric material with short-range order. The ferroelectric film may be fabricated utilizing ALD and/or any other suitable deposition technique. In some embodiments, fabricating the ferroelectric film may deposit a layer of the ferroelectric material to a thickness of 1 nm, 2 nm, 3 nm, etc.

At block 520, an interface layer may be fabricated on the ferroelectric film. Fabricating the interface layer may involve depositing a layer of a dielectric material that is more chemically stable than the ferroelectric material (such as AlOₓ, like Al₂O₃). In some embodiments, the dielectric layer may be deposited to a suitable thickness so that a discontinuous interface layer (e.g., a layer of the dielectric material with islands, pin-holes, and/or pores) may be deposited.

Process 500 may be executed iteratively to fabricate a ferroelectric layer of a suitable thickness and/or suitable numbers of ferroelectric films and interface layers. For example, after executing block 520, process 500 may loop back to block 510 and another ferroelectric film (e.g., a second ferroelectric film) may be fabricated on the first interface layer. The second ferroelectric film may be fabricated by depositing a ferroelectric material on the first interface layer. In some embodiments in which the interface layer includes a discontinuous film of the dielectric layer, fabricating the second ferroelectric film may involve depositing the ferroelectric material on the surface of the discontinuous film of the dielectric layer and directly on the first ferroelectric film underneath the interface layer through the pin-holes and/or pores.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A memory device, comprising:
a first electrode;
a ferroelectric layer fabricated on the first electrode, wherein the ferroelectric layer comprises a plurality of ferroelectric films and a plurality of interface layers stacked alternately, wherein each of the plurality of ferroelectric films comprises a ferroelectric material, and wherein each of the plurality of interface layers comprises at least one dielectric material that is more chemically stable than the ferroelectric material; and
a second electrode fabricated on the ferroelectric layer.

2. The memory device of claim 1, wherein the ferroelectric material comprises a metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1) scandium-doped aluminum nitride (Al₁₋ₓScₓN with x>0.3), titanates (BaTiO₃), niobates (LiNbO₃), or tantalates (NaTaO).

3. The memory device of claim 1, wherein the ferroelectric material is interstitially doped with at least one interstitial dopant, and wherein the at least one interstitial dopant comprises at least one of H, N, C, B, or F.

4. The memory device of claim 1, wherein the plurality of ferroelectric films comprises a first ferroelectric film and a second ferroelectric film, and wherein a first interface layer of the plurality of interface layers is fabricated between the first ferroelectric film and the second ferroelectric film.

5. The memory device of claim 4, wherein the first interface layer comprises a discontinuous film of the dielectric material, wherein at least a portion of the second ferroelectric film is directly fabricated on the first ferroelectric film through pin-holes or pores in the interface layer.

6. The memory device of claim 1, wherein the second electrode is fabricated on a top ferroelectric film of the plurality of ferroelectric films.

7. The memory device of claim 1, wherein the dielectric material comprises aluminum oxide.

8. The memory device of claim 1, wherein the first electrode comprises at least one of tungsten, ruthenium, molybdenum, titanium nitride, tantalum nitride, or tungsten nitride.

9. The memory device of claim 1, wherein the second electrode comprises at least one of tungsten, ruthenium, molybdenum, titanium nitride, tantalum nitride, or tungsten nitride.

10. A method for fabricating a memory device, the method comprising:
fabricating, on a first electrode, a ferroelectric layer, wherein the ferroelectric layer comprises a plurality of ferroelectric films and a plurality of interface layers alternately stacked, wherein each of the plurality of ferroelectric films comprises a ferroelectric material, and wherein each of the plurality of interface layers comprises at least one dielectric material that is more chemically stable than the ferroelectric material; and
fabricating, on the ferroelectric layer, a second electrode.

11. The method of claim 10, wherein the ferroelectric material comprises a metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

12. The method of claim 11, wherein the ferroelectric material is interstitially doped with at least one interstitial dopant, and wherein the interstitial dopant comprises at least one of H, N, C, B, or F.

13. The method of claim 10, wherein fabricating the ferroelectric layer comprises:
fabricating a first ferroelectric film;
fabricating, on the first ferroelectric film, a first interface layer of the plurality of interface layers; and
fabricating a second ferroelectric film on the first interface layer.

14. The method of claim 13, wherein fabricating the first interface layer comprises fabricating a discontinuous film of the dielectric material, wherein at least a portion of the second ferroelectric film is directly fabricated on the first ferroelectric film through the discontinuous film of dielectric material.

15. The method of claim 13, wherein the first ferroelectric film is fabricated by depositing the ferroelectric material using Atomic Layer Deposition (ALD), wherein the first interface layer is fabricated by depositing the dielectric material using ALD.

16. The method of claim 11, wherein the second electrode is fabricated on a top ferroelectric film of the plurality of ferroelectric films.

17. The method of claim 10, wherein the dielectric material comprises aluminum oxide.

18. The method of claim 10, wherein the first electrode comprises at least one of tungsten, ruthenium, molybdenum, titanium nitride, tantalum nitride, or tungsten nitride.

19. The method of claim 10, wherein the second electrode comprises at least one of tungsten, ruthenium, molybdenum, titanium nitride, tantalum nitride, or tungsten nitride.

20. The method of claim 10, further comprising performing heat treatment on the memory device.
